(19) United States
(12) Patent Application Publication
(10) Pub. No.: US 2012/0241310 A1
(43) Pub. Date: Sep. 27, 2012

(54) DEVICE AND METHOD FOR COATING A SUBSTRATE

(76) Inventors: Ulrich Schöpka, Erlangen (DE); Richard Öchsner, Nurnberg (DE); Markus Pfeffer, Nurnberg (DE); Wolfram Maass, Linsengericht (DE); Jürgen Langer, Offenbach am Mai (DE); Berthold Ocker, Hanan (DE)

(21) Appl. No.: 13/510,502

(22) PCT Filed: Nov. 19, 2010
(86) PCT No.: PCT/EP2010/067820

§ 371 Date: Jun. 12, 2012

(30) Foreign Application Priority Data
Nov. 20, 2009 (DE) 10 2009 054 060.1

(51) Int. Cl. C23C 14/46; C23C 14/52

(52) U.S. Cl. 204/192.11; 204/298.03

(57) ABSTRACT

An apparatus for coating a substrate has a vacuum chamber designed to receive the substrate and at least one sputtering target to be ablated during operation of the apparatus by particle bombardment. At least one window is arranged in the wall of the vacuum chamber. A device for determining the wear of the sputtering target, by optically measuring the distance between at least one predefinable point outside the vacuum chamber and at least one predefinable point on the surface of the sputtering target, and including an evaluation device correcting for any parallax offset and/or a geometric distortion.

### BACKGROUND

The invention relates to an apparatus for coating a substrate, comprising a vacuum chamber, the interior of which is designed to receive the substrate to be coated and at least one sputtering target, wherein the sputtering target is intended to be ablated during operation of the apparatus by particle bombardment, and the apparatus furthermore comprises a device for determining the wear of the sputtering target.

DE 102 34 862 A1 discloses an apparatus of the type mentioned in the introduction. According to this known method, it is proposed to use the sputtering target as the source of material for coating a substrate. The wear of material from the sputtering target is brought about by bombarding the surface of the sputtering target with ions from a plasma. In order to prevent thermal damage to the sputtering target, provision can be made to dissipate the thermal energy introduced from the sputtering target by means of water cooling.

This prior art has the disadvantage that, following consumption of the sputtering target, the carrier plate arranged underneath the sputtering target or a positioning device which bears the sputtering target is ablated by the ions impinging from the plasma. If this remains unnoticed by the operating personnel, the layer deposited on the substrate and/or the vacuum chamber which surrounds the apparatus is contaminated by the material of the carrier plate or of the positioning device. If the attack on the carrier plate or the positioning device continues to persist, the cooling ducts which run within these components may be exposed, such that the coolant penetrates into the vacuum chamber and contaminates it. In this case, the rapid increase in pressure which sets in may lead to consequential damage to the vacuum pumps used or to the power supply devices.

To solve this problem, the prior art proposes assessing the wear to the sputtering target using the product of sputtering power and process duration. Since this assessment is error-prone and the wear of the target can proceed inhomogeneously in places, the sputtering target is often exchanged pre-emptively, before the wear limit is reached. This leads to poor utilization of the available material and to unnecessary idle times of the apparatus, since an exchange of the sputtering target requires the time-consuming ventilation and opening of the vacuum chamber.

### SUMMARY

Proceeding from this prior art, the invention is therefore based on the object of specifying a method and an apparatus which can exhaust the material of the sputtering target to the fullest possible extent, without contaminating the coating formed on the substrate by the material of the positioning device. Furthermore, the object of the present invention is to increase the maintenance intervals for an apparatus for coating a substrate.

According to the invention, the object is solved by an apparatus for coating a substrate, comprising a vacuum chamber, the interior of which is adapted to receive the substrate to be coated and at least one sputtering target, which is intended to be ablated during operation of the apparatus by particle bombardment, wherein the apparatus furthermore comprises a device for determining the wear of the sputtering target, wherein at least one window is arranged in the wall of the vacuum chamber, and the device for determining the wear of the sputtering target has a measurement device for optically measuring the distance between at least one predefinable point outside the vacuum chamber and at least one predefinable point on the surface of the sputtering target, and the measurement device furthermore comprises an evaluation device, by means of which a parallax offset and/or a geometric distortion can be corrected.

Furthermore, the object is solved by a method for coating a substrate, in which method the substrate and at least one sputtering target are introduced into the interior of a vacuum chamber and the sputtering target is ablated by particle bombardment and the wear thereof is determined, wherein the distance between at least one predefinable point outside the vacuum chamber and at least one predefinable point on the surface of the sputtering target is optically measured through a window arranged in the wall of the vacuum chamber, and the measured distances are supplied to an evaluation device, which corrects at least one parallax offset and/or an optical distortion.

It is proposed, according to the invention, to insert a window in the wall of the vacuum chamber which surrounds the apparatus for coating a substrate. Within the context of the present invention, a window is understood to mean a region in the wall of the vacuum chamber which is transparent to an electromagnetic radiation of a predefinable wavelength range. By way of example, the material of the window may comprise glass or quartz.

For optically measuring the distance between at least one predefinable point outside the vacuum chamber and at least one predefinable point on the surface of the sputtering target, an electromagnetic radiation of a predefinable wavelength and/or of a predefinable wavelength range is directed through the window onto the surface of the sputtering target, where it is reflected. The returned beam of light can be received and evaluated by the proposed measurement device. By way of example, the distance between the measurement device and the target surface can be determined by means of laser triangulation. In other embodiments of the invention, the distance can be determined by evaluating the phase information of the returned light or by propagation time measurement. For this purpose, the light which is emitted by the device for optical measurement of the distance can be pulsed. The wavelength can be between 3 μm and 200 nm. In some embodiments, the wavelength can be between 700 nm and 500 nm.

The particle bombardment removing the sputtering target can be effected by positively or negatively charged ions and/or neutral atoms. In some embodiments of the invention, the particle bombardment can be effected by electrons or photons.

Progressive wear of the sputtering target increases the distance between the predefinable point outside the vacuum chamber and the at least one predefinable point on the surface of the sputtering target. As a result, the user can determine the thickness of the sputtering target at a predefinable point in time. If this change in the distance is greater than or equal to the known thickness of the sputtering target, the user of the apparatus for coating a substrate receives a clear indication that the sputtering target is completely exhausted or has reached its wear limit. In this way, the method for coating a substrate can be interrupted before the material of the positioning device and/or of the carrier plate for the sputtering target is ablated by the ion bombardment and contaminates the layer deposited on the substrate. This also reliably prevents the material of these components from being ablated to such an extent that the coolant circulating in cooling ducts within the positioning device escapes at the vacuum-side delimiting surface.

If the beam of light used for optically measuring the distance impinges at an angle which differs from the surface normal of the target, a distortion of the measured values or a parallax error may arise. In some embodiments of the invention, provision may be made for the measurement device to comprise an evaluation device or to be connected to an evaluation device, by means of which a parallax offset and/or a geometric distortion can be corrected. In this way, the thickness of the sputtering target can be determined with a relatively high degree of accuracy. In some embodiments of the invention, the sputtering target can move on a circular path in front of the measurement device. In this case, the evaluation device can be designed to correct a parabolic distortion of the measured values recorded by the measurement device. The evaluation device can comprise a microprocessor or a microcontroller. In some embodiments, the evaluation device can comprise a software which applies a corresponding correction method to the measured values, if the software is executed on a computer.

In some embodiments of the invention, the apparatus can furthermore comprise a positioning device, with which the sputtering target can be moved from an operating position into a measuring position. In this respect, the operating position denotes a position of the sputtering target in which the latter is arranged lying opposite the substrate to be coated and is ablated by impinging ions, which impinge from a plasma on the surface of the sputtering target. The measuring position, by contrast, denotes a position in which the surface of the sputtering target can be observed through the window in the wall of the vacuum chamber. In some embodiments, the measuring position and the operating position can be the same position of the sputtering target within the vacuum chamber. In other embodiments of the invention, the measuring position and the operating position may differ spatially. In this case, provision may be made for the target to be moved in the detection region of the measurement device as it is being transferred from the operating position into the measuring position, such that measured values are recorded along a line defined by the direction of movement.

In some embodiments of the invention, the positioning device can comprise a cylinder, on the lateral surface of which there is arranged at least one sputtering target. In this embodiment, the movement from an operating position into a measuring position can be effected by simple rotation of the cylinder. In this case, the rotation can be imparted by an electric motor arranged within the vacuum chamber, or by a drive which is arranged outside the vacuum chamber and is connected to the cylinder by means of a magnetic coupling.

The measurement device can be arranged movably on a mount. This makes it possible to determine the thickness or the wear of the sputtering target at a plurality of points lying along the direction of movement. In this way, it is possible to establish whether the sputtering target is ablated uniformly. It is thereby possible to avoid a situation where the underlying material of the positioning device is ablated at an individual point of the surface of the sputtering target, even though the sputtering target still has a sufficient thickness at other points. In some embodiments of the invention, a three-dimensional measurement of the surface of the sputtering target can be provided by two orthogonal directions of movement between the target and the measurement device. In some embodiments of the invention, the measurement device can have a line detector for reflected radiation, in order to perform a three-dimensional measurement of the surface of the sputtering target by a relative movement between the target and the measurement device in one direction. In some embodiments of the invention, the measurement device can have an area detector for reflected radiation, in order to perform a three-dimensional measurement of the surface of the sputtering target even without movement between the target and the measurement device.

In some embodiments of the invention, the apparatus for coating a substrate can furthermore comprise a regulating device, by means of which the wear rate of the sputtering target is regulated to a predefinable desired value and to which a measured value which characterizes the state of the sputtering target can be supplied from the device for determining the wear of the sputtering target. In some embodiments, the regulating device can influence the distance between the surface of the sputtering target and the surface of the substrate and/or the distance between the surface of the sputtering target and the magnetron as a manipulated variable. In this way, the wear rate can be determined from the continuous monitoring of the thickness of the sputtering target, and can be regulated with a high degree of accuracy to a predefinable desired value. In this embodiment, particularly uniform layer thicknesses can be deposited on the substrate.

In some embodiments, the measurement device can be designed to determine the distance between at least one predefinable point outside the vacuum chamber and a plurality of predefinable points on the surface of the sputtering target. This can encompass the use of a line sensor in the measurement device. The layer thickness of the sputtering target can thereby be determined in a relatively large surface region. If the sputtering target is moved past the thus equipped measurement device, the layer thickness can be measured over the entire surface in only one pass. This also makes it possible to detect nonuniform wear of the sputtering target and the formation of grooves on the surface of the sputtering target, in that the position and the extreme points are determined from the measured values.

### BRIEF DESCRIPTION OF THE DRAWINGS

In the text which follows, the invention is to be explained in more detail with reference to figures, without limiting the general concept of the invention. In the figures:

FIG. 1 shows the outline of an apparatus for coating a substrate, in cross section;

FIG. 2 shows the elevation of an apparatus for coating a substrate, in cross section;

FIG. 3 shows the principle of the fine correction of the measured data;

FIG. 4 shows the raw data recorded by the measurement device according to one embodiment of the invention;

FIG. 5 shows an excerpt from the raw data shown in FIG. 4; and

FIG. 6 shows the data after the correction proposed according to the invention.

### DESCRIPTION OF PREFERRED EMBODIMENTS

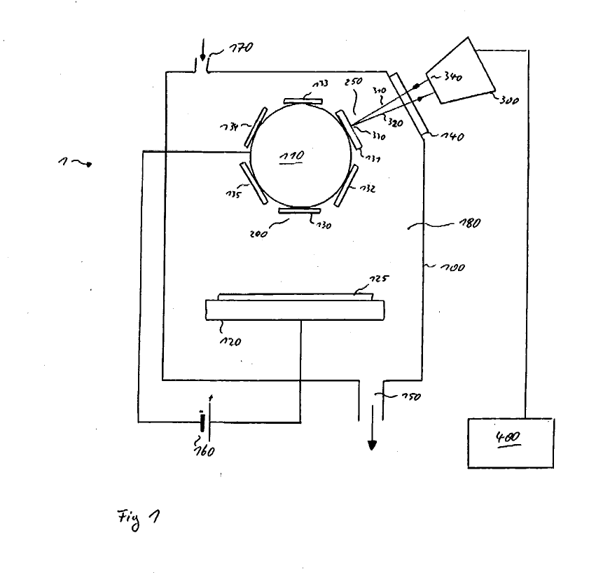

FIG. 1 shows the outline of an apparatus 1 for coating a substrate. The apparatus 1 is surrounded by a vacuum chamber 100. The vacuum chamber 100 can be produced, for example, from a metal or an alloy. In some embodiments, the vacuum chamber can be produced from an aluminum alloy or a high-grade steel.

The vacuum chamber 100 has a connecting flange 150, via which the vacuum chamber 100 is connected to a vacuum pump (not shown). In some embodiments, a vacuum of less than 1×10⁻⁵ mbar, less than 1×10⁻⁶ mbar or less than 1×10⁻⁸ mbar can be generated by means of the vacuum pump in the vacuum chamber.

Furthermore, the vacuum chamber 100 has at least one gas feed 170. A sputtering gas, for example argon, nitrogen or oxygen, can be admitted into the vacuum chamber via the gas feed 170. During operation of the sputtering system, the pressure in the interior of the vacuum chamber can be regulated via the gas feed 170 to approximately 1×10⁻² mbar to approximately 10 mbar, in some embodiments to approximately 5×10⁻² mbar to approximately 1 mbar.

The substrate 125 to be coated is arranged on a substrate holder 120. The substrate holder 120 can be designed to receive at least one substrate 125. The substrate holder 120 can have a heating system or a cooling system, with which the substrate 125 can be brought to a predefinable temperature. The substrate 125 can be a semiconductor material, a tool or an architectural glass. Accordingly, the coating to be deposited on the substrate 125 can be a wear-resistant layer, a metal layer, a thermal barrier coating, a sliding layer or a similar functional coating.

The coating to be deposited on the substrate 125 comprises at least one element which is deposited from at least one of the sputtering targets 130, 131, 132, 133, 134 and 135. In addition; the coating to be deposited can comprise further elements which are supplied from the gas phase, for example as reactive gas or as an unavoidable impurity from the residual gas. The sputtering targets 130, 131, 132, 133, 134 and 135 can have an identical or a different chemical composition.

The sputtering targets 130 to 135 are arranged on a positioning device 110. In the embodiment illustrated, the positioning device 110 is in the form of a rotatable cylinder. In this way, one sputtering target of the six sputtering targets 130 to 135 shown in FIG. 1 can be brought in each case into an operating position 200. In the operating position 200, the selected sputtering target, the target 130 in FIG. 1, is located approximately opposite the substrate 125 to be coated. In other embodiments of the invention, the number of sputtering targets can be greater than or less than six. The invention does not teach the adherence to a certain number as a principle of solution.

During operation of the coating system, a potential difference is applied by means of a voltage source 160 between the substrate holder 120 and the sputtering target 130 in the operating position 200. The potential difference may be constant over time as a DC voltage or may vary over time as an AC voltage. The potential difference can have the effect that a plasma forms between the surface of the substrate 125 to be coated and the surface of the sputtering target 130 located in the operating position 200. Ions of the sputtering gas which is fed via the connecting flange 170 can be accelerated from the plasma onto the surface of the sputtering target 130. The material of the sputtering target 130 is ablated as a result, with the atoms which are detached from the sputtering target at least partially forming the desired coating on the substrate 125. However, the invention is not restricted to the exemplary embodiment shown. In other embodiments of the invention, the plasma can also be generated by means of an electromagnetic radiation, for example a microwave radiation. In some embodiments of the invention, provision may be made of at least one device for generating magnetic fields, in order to limit the plasma to a predefinable spatial region between the sputtering target 130 and the substrate 125 to be coated and/or in order to increase the energy density in the plasma.

Once the sputtering target 130 has been atomized completely at least over a partial area, the positioning device 110 and/or an optional carrier plate arranged underneath the target is exposed to attack by the plasma. This has the effect that the coating deposited on the substrate 125 is contaminated with the material of these components. If cooling ducts are arranged within the volume of the positioning device 110 and/or the carrier plate, the coolant, for example water or compressed air, which circulates in the cooling ducts can escape into the interior 180 of the vacuum chamber 100. In order to prevent these disadvantages, provision is made according to the invention to move the target 130 from the operating position 200 into the measuring position 250 by rotation of the positioning device 110. In FIG. 1, the sputtering target 130 is shown in the measuring position 250. It goes without saying, however, that all sputtering targets 130 to 135 can be moved into the measuring position 250 by rotation of the positioning device 110, either cyclically or in an event-driven manner, for example if the user of the apparatus 1 would like to determine the wear of the sputtering target 130.

In the measuring position 250, the surface of the sputtering target 131 is visible through a window 140. The window 140 is made of a material which is transparent to the electromagnetic radiation 310 emitted by the measurement device 300. Transparency should always be assumed when at least a fraction of the electromagnetic radiation can pass through the window and impinge on the surface of the sputtering target 131. By way of example, the window 140 can comprise glass or quartz or beryllium or consist thereof.

In order to determine the remaining thickness of the sputtering target 131, provision is made for the distance between at least one predefinable point 340 outside the vacuum chamber and at least one predefinable point 330 on the surface of the sputtering target 131 to be determined by means of the measurement device 300. By way of example, the at least one predefinable point 340 can be defined by the position of an outlet lens or of a sensor or of a deflection mirror or of another component of the measurement device 300. In other embodiments, the predefinable point 340 can be defined by the position of a laser which generates the measuring beam 310.

The measuring beam 310 emerging from the measurement device 300 is returned by the surface of the sputtering target 131 at point 330. The returned beam of light 320 can leave the vacuum chamber through the window 140 and can be ascertained using the measurement device 300. The distance between the points 340 and 330 can then be determined from the optical measurement, for example by the phase shift between the measuring beam 310 and the returned beam 320, the propagation time of the light or by triangulation. In some embodiments of the invention, the measurement device 300 can comprise a spatially resolving sensor, in order to thereby determine the position of a plurality of points 330 on the surface of the sputtering target 131. It is thus possible to measure not only an individual point 330, but also a plurality of points 330 of the surface of the sputtering target 131. The plurality of points 330 can be arranged along a line or can be distributed areally over the surface of the sputtering target.

With increasing wear of the sputtering target 131, the point 330 on the surface of the sputtering target 131 migrates in the direction of the positioning device 110. The distance between the points 340 and 330 thereby becomes greater. The increase in the distance corresponds at the same time to the decrease in the thickness of the sputtering target 131. If the sputtering target 131 is rotated by means of the positioning device 110 in front of the window 140, the entire width of the surface of the target 131 which is visible in FIG. 1 can be measured. In this way, it is also possible to detect nonuniform wear of the sputtering target 131.

The measured values generated by the measurement device 300 can be processed further by means of an evaluation device 400. The evaluation device 400 can correct, for example, a parallax offset and/or a geometric distortion. Such a geometric distortion can arise, for example, from the rotation of the positioning device 110. In this way, a planar surface of a sputtering target 131 is mapped into a parabola. The evaluation device 400 can be designed to visualize or to store the measured values obtained. In other embodiments of the invention, the evaluation device 400 can generate a control and/or regulating signal, which influences the coating method which proceeds in the interior 180 of the vacuum chamber 100. By way of example, in this way nonuniform wear of the sputtering target 131 with the formation of grooves can be detected, or a desired coating rate can be retained.

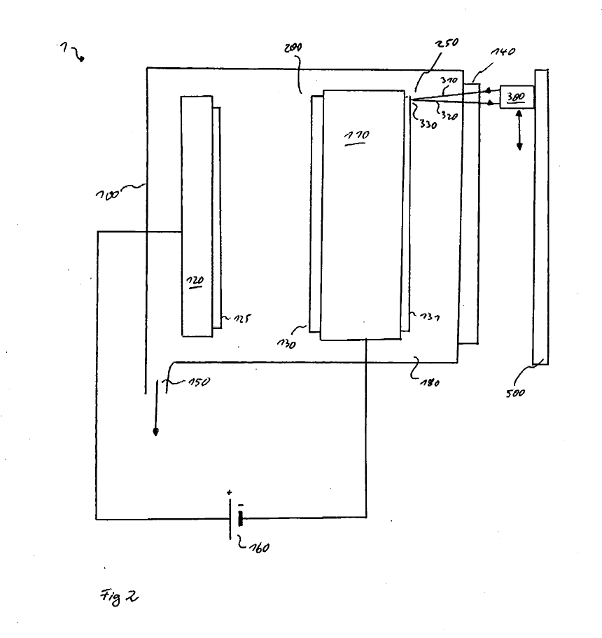

FIG. 2 shows the apparatus 1 shown in FIG. 1 in elevation. FIG. 2, in turn, shows the vacuum chamber 100 with the substrate holder 120 arranged therein and a substrate 125 to be coated, which is arranged on the latter. A sputtering target 130 is arranged lying opposite the substrate 125 and is located in the operating position 200. During operation of the apparatus 1, the sputtering target 130 is ablated in the operating position 200, as explained above in connection with FIG. 1.

FIG. 2 also shows a sputtering target 131, which is located in the measuring position 250. In the measuring position 250, the sputtering target 131 is located opposite the window 140. The window 140 shown has an elongate form, which corresponds approximately to the longitudinal extent of the sputtering target 131. In this way, the entire surface of the sputtering target 131 can be observed through the window 140.

FIG. 2 also shows the measurement device 300, which emits a measuring beam 310 onto the surface of the sputtering target 131. The measuring beam 310 is reflected on the surface of the sputtering target 131 at point 330 and returned as a beam of light 320 into the measurement device 300. In this way, the wear of the sputtering target 131 at point 330 can be determined.

In order to record a further measurement point 330 at another location on the surface of the sputtering target 131, the measurement device 300 is mounted movably on a mount 500. The measurement device 300 can thus be moved along the longitudinal extent of the sputtering target 131 in order to thereby record a plurality of measured values. If in addition the positioning device 110 is rotated, as explained in connection with FIG. 1, the entire surface of the sputtering target 131 is accessible to the measurement device 300. In this way, the thickness of the sputtering target 131 can be measured over the entire area.

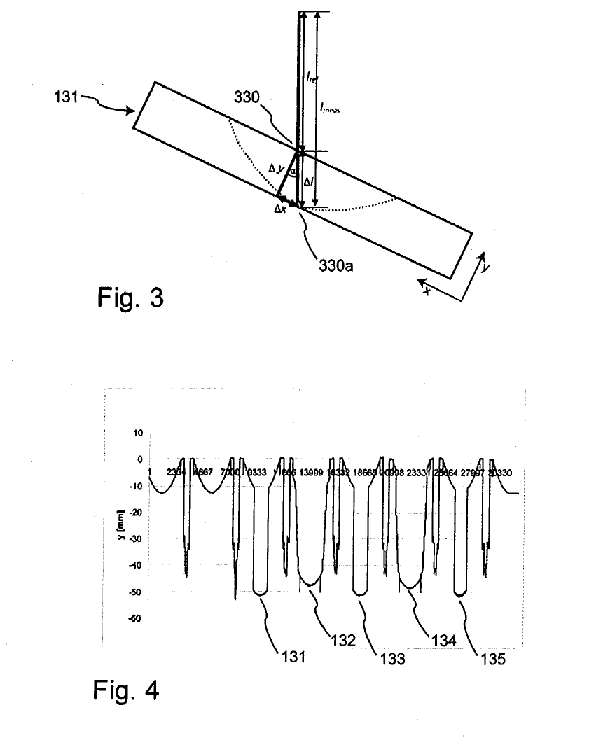

FIG. 3 shows the principle of the fine correction of the measured data which were obtained from a rectangular target 131 arranged on a positioning device 110. Here, the original surface of a new target is shown as a solid line, and an exemplary surface profile which results during operation by the wear of the target is shown as dashed lines.

The positioning device 110 comprises a cylinder mounted such that it can rotate about its longitudinal axis. As already explained with reference to FIG. 1, a window 140 is arranged laterally alongside the cylinder, and through this window it is possible to observe the surface of the target 131 which is located directly in front of the window 140. The positioning device 110 makes it possible to move various targets into the measuring position in front of the window. During this movement, the entire width of the target 131 can be moved in front of the measurement device 300, such that, during the rotation of the positioning device 110, the cross section or a profile can be created along a sectional plane defined by the direction of movement.

Since a planar surface of the target 131 does not follow the surface of the cylinder, the exact distance can only be measured directly for a measurement point 330 which lies on the line of intersection between the target and the cylinder. With an increasing distance between the measurement point and the line of intersection, the distance between the sensor and the target surface becomes ever smaller, as a result of which a parabolic distortion of the topography in the y direction and also compression in the x direction arise. These distortions can be corrected by means of the proposed evaluation device 400, in order to obtain the desired, actual surface information.

Since the distance between the measured point 330a and the measurement device 300 increases by the magnitude Δl as a result of the wear of the target 131, inclined incidence of the laser light at a viewing angle α to the surface normal leads to a displacement Δx of the measurement point on the surface. In some embodiments of the invention, this displacement can likewise be corrected. In this case, the displacement Δx and the current wear Δy of the target are calculated as a function of the angle of incidence α from the measured wear Δl of the target in accordance with:

Δy=Δl·cos α

Δx=Δl·sin α

The measured wear Δl of the target after a predefinable operating time is obtained from the difference between the distance lₘₑₐₛ measured after a predefinable operating time and the distance l_{ref} measured at the start of the coating method. The correction according to the invention of the parabolic distortion is therefore based on a comparison of the current measured data with the measured data of a new, unconsumed target of the same type.

In some embodiments of the invention, the correction method can be carried out in multiple stages. In the first step, the reference measured data of the new target l_{ref} are subtracted from the current measured data lₘₑₐₛ in order to roughly correct the measured data in the y direction and to project the parabola into the plane. Then, in the second method step, a rough correction is effected in the x direction, based on a calculated correction function which was determined from a planar, i.e. new, target. In this case, the correction function can be determined from the geometric properties of the apparatus 1 for coating a substrate and of the target 131 or of the positioning device 110. In this correction, the x distances between the individual data points are determined and adapted on the basis of the radius of the cylinder and of the rotational speed in each measurement point and also of the measurement frequency.

The wear of the target and the viewing angle α give rise to additional displacements, one distortion in the y direction (Δy) and, resulting therefrom and also from the inclined incidence of the laser light, a further distortion in the x direction (Δx). These additional distortions can be remedied in the third method step. The x position of the point on a new target and also Δl are known from the preceding correction. With the aid of the viewing angle α, Δx and Δy can thus be calculated.

In the text which follows, an exemplary embodiment of the measurement method according to the invention is to be indicated. In this respect, FIG. 4 shows the raw data recorded by the measurement device according to one embodiment of the invention. In the example shown, five targets 131, 132, 133, 134 and 135 are arranged on the lateral surface of a cylindrical positioning device 110. With complete rotation of the positioning device 110, each target is moved once into the detection region of the measurement device 330, such that the raw data shown in FIG. 4 can be recorded. Here, the ordinate shows the distance between a predefinable, fixed point, which can be defined for example by the position of the measurement device 330. The abscissa shows the consecutive number of data points, which can be converted by way of the angular speed and the measurement frequency into a coordinate on the lateral surface of the cylinder or an x coordinate on the target.

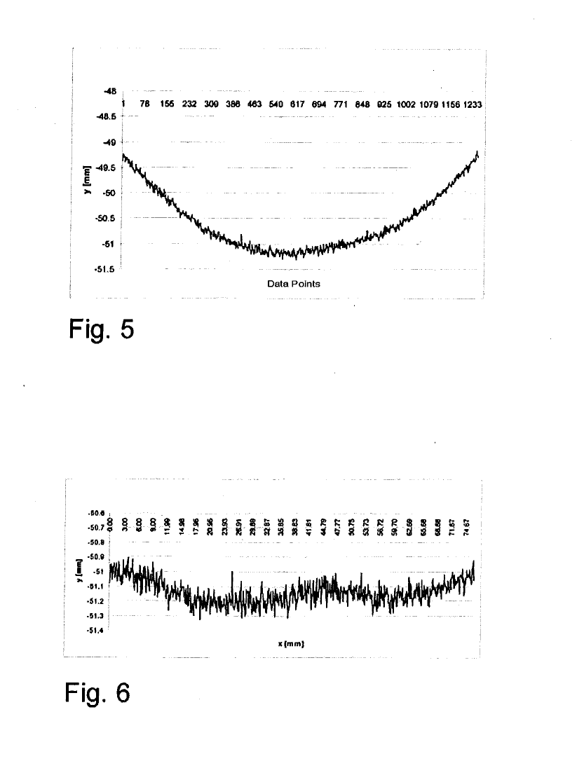

FIG. 5 shows an enlarged excerpt from the raw data shown in FIG. 4. Here, the region shown in FIG. 5 corresponds to the measured values which were recorded on an individual sputtering target of the in total five sputtering targets. The measured values shown were recorded on a target which had already been used in a coating method and therefore exhibits material wear or wear. It can be seen from FIG. 5 that this wear is superposed on the measurement device as a result of the geometric distortions, and therefore cannot be ascertained by the user of the sputtering system 1.

FIG. 6 shows the data as shown in FIG. 5 after the correction method proposed according to the invention has been carried out. It can be seen from FIG. 6 that the target surface has two grooves or flutes having a depth of approximately 0.2-0.3 mm. The wear of the target material can thus be determined with a high degree of accuracy by the method according to the invention, without interrupting the operation of the apparatus 1 for coating a substrate.

The above description should not be regarded as restrictive, but as explanatory. The description and the claims which follow should be understood as meaning that a feature which is mentioned is present in at least one embodiment of the invention. This does not exclude the presence of further features. Wherever the claims or the description define “first” and “second” features, this designation serves for distinguishing between two identical features, without giving them any priority.

1.-16. (canceled)

17. An apparatus for coating a substrate, comprising
a vacuum chamber, the interior of which is adapted to receive the substrate to be coated and wherein at least one window is arranged in the wall of the vacuum chamber,
at least one sputtering target, which is adapted to be ablated during operation of the apparatus by particle bombardment,
a device for determining the wear of the sputtering target, comprising a measurement device for optically measuring the distance between at least one predefinable point outside the vacuum chamber and at least one predefinable point on the surface of the sputtering target through said window, wherein the measurement device is coupled to an evaluation device being adapted to correct any of a parallax offset or a geometric distortion.

18. The apparatus as claimed in claim 17, comprising further a positioning device being adapted to move the sputtering target from an operating position into a measuring position.

19. The apparatus as claimed in claim 18, wherein the positioning device comprises a cylinder, on the lateral surface of which there is arranged at least one sputtering target.

20. The apparatus as claimed in claim 17, wherein the measurement device comprises any of a device for laser triangulation and/or at least one interferometer.

21. The apparatus as claimed in claim 17, wherein the measurement device is designed to determine the distance between at least one predefinable point outside the vacuum chamber and a plurality of predefinable points on the surface of the sputtering target.

22. The apparatus as claimed in claim 17, wherein the measurement device is supported movably on a mount.

23. The apparatus as claimed in claim 17, furthermore comprising a control device for controlling the wear rate of the sputtering target to a predefinable value, wherein the control device is adapted to receive a measured value characterizing the wear of the sputtering target from the measurement device.

24. An apparatus for coating a substrate, comprising
a vacuum chamber, the interior of which is adapted to receive the substrate to be coated and wherein at least one window is arranged in the wall of the vacuum chamber,
at least one sputtering target, which is adapted to be ablated during operation of the apparatus by particle bombardment,
a device for determining the wear of the sputtering target, comprising a measurement device comprising any of a device for laser triangulation and/or at least one interferometer, wherein the measurement device is coupled to an evaluation device being adapted to correct any of a parallax offset or a geometric distortion of acquired data.

25. The apparatus as claimed in claim 24, comprising further a positioning device being adapted to move the sputtering target from an operating position into a measuring position.

26. The apparatus as claimed in claim 25, wherein the positioning device comprises a cylinder, on the lateral surface of which there is arranged at least one sputtering target.

27. The apparatus as claimed in claim 24, wherein the measurement device is designed to determine the distance between at least one predefinable point outside the vacuum chamber and a plurality of predefinable points on the surface of the sputtering target.

28. The apparatus as claimed in claim 24, comprising further a mount which is adapted to movably support the measurement device.

29. The apparatus as claimed in claim 24, furthermore comprising a control device for controlling the wear rate of the sputtering target to a predefinable value, wherein the control device is adapted to receive a measured value characterizing the wear of the sputtering target from the measurement device.

30. A method for coating a substrate, comprising the following steps:
introducing the substrate and at least one sputtering target into the interior of a vacuum chamber,
ablating the sputtering target by particle bombardment
determining the wear of the sputtering target by
optically measuring the distance between at least one predefinable point outside the vacuum chamber and at least one predefinable point on the surface of the sputtering target through a window being arranged in the wall of the vacuum chamber
supplying the measured distances to an evaluation device, which corrects at least any of a parallax offset and/or an optical distortion.

31. The method as claimed in claim 30, wherein the coating process is stopped if the thickness of the sputtering target falls below a predefinable value.

32. The method as claimed in claim 30, wherein the correction of a parallax offset and/or an optical distortion comprises the steps of
acquiring reference measured data l_{ref} of a new target
acquiring measured data lₘₑₐₛ of the target under operation
subtracting l_{ref} from lₘₑₐₛ.

33. The method as claimed in claim 30, wherein the correction of a parallax offset and/or an optical distortion comprises the steps of
Determining at least one correction function
Correcting the measured data by applying said correction function, so that a distorsion in x direction is corrected.

34. The method as claimed in claim 33, wherein the correction function is determined on a planar target and represents geometric properties of the apparatus for coating a substrate and of the target.

35. The method as claimed in claim 30, wherein a correction of the measured data from the viewing angle α to the surface normal and the measured wear Δl of the target is effected in accordance with the following equation:
Δy=Δl·cos α
Δx=Δl·sin α
